(19) United States
(12) Patent Application Publication
(10) Pub. No.: US 2020/0194700 A1
(43) Pub. Date: Jun. 18, 2020

(54) HETEROJUNCTION SOLAR CELL WITH HOLE TRANSPORT LAYER AND PREPARATION METHOD THEREOF

(71) Applicant: SOUTH CHINA UNIVERSITY OF TECHNOLOGY, Guangzhou (CN)

(72) Inventors: Shuguang ZHANG, Guangzhou (CN); Lei WEN, Guangzhou (CN); Zhenzhu XU, Guangzhou (CN); Yuefeng YU, Guangzhou (CN)

(73) Assignee: SOUTH CHINA UNIVERSITY OF TECHNOLOGY, Guangzhou (CN)

(21) Appl. No.: 16/713,481

(22) Filed: Dec. 13, 2019

(30) Foreign Application Priority Data
Dec. 14, 2018 (CN) 201811531039.0

(51) Int. Cl. H01L 51/42; H01L 51/00

(52) U.S. Cl. CPC H01L 51/4213; H01L 51/0003; H01L 51/0056; H01L 2251/301; H01L 51/006

(57) ABSTRACT

Disclosed is a heterojunction solar cell with a hole transport layer. The solar cell includes a bottom electrode, a GaAs substrate, an InGaAs epitaxial layer, a hole transport layer, a molybdenum disulfide layer and a top electrode in order from bottom to top; the hole transport layer is a 2,2′,7,7′-tetra[N,N-bis(4-methoxyphenyl)amino]-9,9′-spirobifluorene film. Also disclosed is a preparation method of the heterojunction solar cell with a hole transport layer. The heterojunction solar cell of the present invention not only has simple preparation process and low process cost, but also has high photoelectric conversion efficiency, and the preparation method is an effective method for preparing a novel heterojunction solar cell.

### TECHNICAL FIELD

The present invention relates to the technical field of solar cells, and in particular, to a heterojunction solar cell with a hole transport layer and a preparation method thereof.

### BACKGROUND

Molybdenum disulfide is a two-dimensional carbon nanomaterial with a hexagonal honeycomb lattice composed of a carbon atom by an sp² hybrid orbital. It has the characteristics of high transmittance and high carrier mobility, etc., and has important application prospects in energy, materials science, micro-nano fabrication, biomedicine and drug delivery, etc. Therefore, it is considered to be a revolutionary material in the future. However, conventional molybdenum disulfide has no band gap and cannot form a PN junction with other semiconductor materials to construct a novel photoelectric device. Layered molybdenum disulfide (MoS₂) is a new type of two-dimensional atomic crystal material that has attracted great interest in recent years. Unlike molybdenum disulfide, layered molybdenum disulfide is a direct band-gap semiconductor material with a forbidden band width of about 1.8 eV, and can form a heterojunction with InGaAs. The heterojunction has an excellent photovoltaic effect and can be prepared into an InGaAs-molybdenum disulfide heterojunction solar cell. Compared with traditional silicon-based solar cells and GaAs-based solar cells, this cell has the characteristics such as low cost, simple preparation process and good stability, and has excellent photoelectric performance.

### SUMMARY

In order to overcome the above disadvantages and shortcomings of the prior art, an objective of the present invention is to provide a heterojunction solar cell with a hole transport layer, which greatly improves the transport and collection efficiency of the hole transport layer through the application of a new hole transport layer, and can effectively improve the photoelectric conversion efficiency of the solar cell.

Another objective of the present invention is to provide a preparation method of the heterojunction solar cell with a hole transport layer.

The objectives of the present invention are achieved by the following technical solutions.

A heterojunction solar cell with a hole transport layer, where the solar cell includes a bottom electrode, a GaAs substrate, an InGaAs epitaxial layer, a hole transport layer, a molybdenum disulfide layer and a top electrode in order from bottom to top; the hole transport layer is a 2,2′,7,7′-tetra[N,N-bis(4-methoxyphenyl)amino]-9,9′-spirobifluorene film.

The hole transport layer has a thickness of 50-500 nm.

The GaAs substrate is N-type, having a size of 1-4 inches, and a doping concentration of 1×10¹⁷-3×10¹⁸ cm⁻³.

The InGaAs epitaxial layer is N-type InGaAs, having a size of 1-4 inches, a doping concentration of 1×10¹⁷-4×10¹⁸ cm⁻³, and a thickness of 100-1,000 nm.

The number of layers of the molybdenum disulfide is 1-8.

The bottom electrode has a thickness of 40-600 nm.

The top electrode is a silver conductive silver adhesive or silver wire, and has a thickness of 0.2-1 82 m.

A preparation method of the heterojunction solar cell with a hole transport layer, including the following steps:

(1) preparation of the bottom electrode: fixing the GaAs substrate on a disk, and evaporating a layer of bottom electrode on the back of the GaAs substrate by an electron beam evaporation method, where the evaporation temperature is 10-100° C., and the evaporation time is 10-60 min;

(2) growing of the InGaAs epitaxial layer: placing the GaAs substrate evaporated with the bottom electrode into a molecular beam epitaxy system to grow the InGaAs epitaxial layer;

(3) dicing: dicing the GaAs substrate on which the InGaAs epitaxial layer is grown into slices by laser scribing;

(4) cleaning the substrate;

(5) preparation of 2,2′,7,7′-tetra[N,N-bis(4-methoxyphenyl)amino]-9,9′-spirobifluorene as the hole transport layer by spin coating: fixing the substrate on a spin coater, and preparing the 2,2′,7,7′-tetra[N,N-bis(4-methoxyphenyl)amino]-9,9′-spirobifluorene by spin coating, where the spin coating rate during spin coating is 1,000-5,000 rpm, and the spin coating time is 10-60 s;

(6) transfer of the molybdenum disulfide: growing the molybdenum disulfide on a copper foil by a chemical vapor deposition method, and after the growth is completed, coating a layer of polymethyl methacrylate (PMMA) on the surface of the molybdenum disulfide as a protection and support layer; before transfer, first taking a substrate slice evaporated with the hole transport layer to transfer the prepared molybdenum disulfide; first, etching the copper foil away with a FeCl₃ solution, transferring the molybdenum disulfide to ultrapure water, then, laminating the molybdenum disulfide on the surface of the hole transport layer by a van der Waals force of a water molecule, and allowing to stand for half an hour to dry naturally;

(7) post-treatment: placing the device with the transferred molybdenum disulfide on a heating plate, and baking at a temperature of 60-200° C. for 5-30 min to remove moisture inside the molybdenum disulfide, so that the molybdenum disulfide is more tightly laminated with the hole transport layer; then immersing in acetone at 20-80° C. for 5-15 min to remove the PMMA on the surface of the molybdenum disulfide; and

(8) preparation of the top electrode: first, taping around the edge of the molybdenum disulfide, and then making a circle of conductive silver adhesive on the edge of the molybdenum disulfide with an injector, the conductive silver adhesive having a thickness of 0.2-2 μm; and finally, baking the conductive silver adhesive at 30-100° C. for about 2-20 min to fully cure the conductive silver adhesive.

The conductive silver adhesive is elongated or round on the surface of the molybdenum disulfide.

The cleaning the substrate according to the step (4) is specifically: after dicing, sequentially ultrasonically cleaning the substrate for 5-20 min by acetone, isopropyl alcohol and ultrapure water, respectively, and then drying the surface by a dryer for use.

Compared with the prior art, the present invention has the following advantages and beneficial effects.

(1) The present invention prepares a heterojunction solar cell with a hole transport layer, and a novel structure InGaAs-molybdenum disulfide heterojunction solar cell is prepared by realizing the separation of an electron-hole pair by a built-in electric field generated by an InGaAs/molybdenum disulfide heterojunction.

(2) The present invention inserts a layer of 2,2′,7,7′-tetra[N,N-bis(4-methoxyphenyl)amino]-9,9′-spirobifluorene (Spiro-OMeTAD) in the middle of the InGaAs-molybdenum disulfide heterojunction solar cell as a hole transport layer; the hole transport layer can effectively conduct a hole while blocking an electron, and effectively separate and collect the electron and the hole, thereby reducing the recombination probability of the electron and the hole, increasing a photo-generated current, and finally achieving high photoelectric conversion efficiency of the solar cell.

(3) The preparation method of the present invention is simple and effective, and effectively simplifies the structure of the cell, realizes low preparation process cost, and obviously improves the photoelectric conversion efficiency of the cell.

### BRIEF DESCRIPTION OF THE DRAWINGS

FIG. 1 is a schematic structural diagram of an InGaAs-molybdenum disulfide heterojunction solar cell with a hole transport layer according to an embodiment of the present invention.

FIG. 2 is a diagram showing a current-voltage relation curve of an InGaAs-molybdenum disulfide heterojunction solar cell before and after the addition of a hole transport layer according to an embodiment of the present invention.

### DETAILED DESCRIPTION

The present invention is further described below with reference to the embodiments, but the implementations of the present invention are not limited thereto.

### Embodiment 1

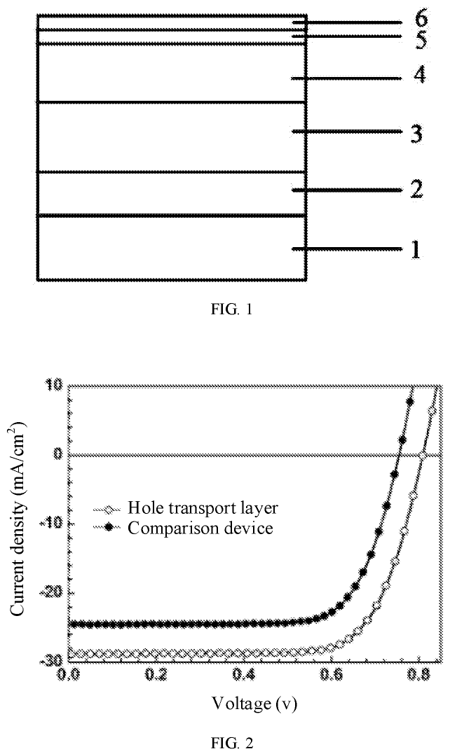

As shown in FIG. 1, an InGaAs-molybdenum disulfide heterojunction solar cell in the present embodiment includes a gold bottom electrode 1, a GaAs substrate 2, an InGaAs epitaxial layer 3, a hole transport layer 4, molybdenum disulfide 5 and a conductive silver adhesive top electrode 6 in order from bottom to top.

A preparation method of the InGaAs-molybdenum disulfide heterojunction solar cell with a hole transport layer in the present embodiment includes the following steps:

(1) Preparation of the bottom electrode: fix a 2-inch GaAs substrate on a disk, and evaporate a layer of Au electrode on the back of the GaAs substrate by an electron beam evaporation system, where the evaporation temperature is 40° C., the evaporation time is 20 min, and the Au electrode has a thickness of 100 nm.

(2) Growing of the InGaAs epitaxial layer: place the GaAs substrate evaporated with the Au electrode into a molecular beam epitaxy system to grow the InGaAs epitaxial layer, where the InGaAs epitaxial layer has a thickness of 500 nm, and a doping concentration of 2×10¹⁷ cm⁻³.

(3) Dicing: dice the GaAs substrate on which the InGaAs epitaxial layer is grown into slices having a size of 1 cm² by laser scribing.

(4) Cleaning: after dicing, sequentially ultrasonically clean the substrate for 10 min by acetone, isopropyl alcohol and ultrapure water, respectively, and then dry the surface by a dryer for use.

(5) Preparation of 2,2′,7,7′-tetra[N,N-bis(4-methoxyphenyl)amino]-9,9′-spirobifluorene (Spiro-OMeTAD) as the hole transport layer by spin coating: fix the substrate on a spin coater, and prepare the 2,2′,7,7′-tetra[N,N-bis(4-methoxyphenyl)amino]-9,9′-spirobifluorene (Spiro-OMeTAD) by spin coating, where the spin coating rate during spin coating is 4,000 rpm, the spin coating time is 40 s, and the prepared hole transport layer has a thickness of 250 nm.

(6) Transfer of the molybdenum disulfide: grow the molybdenum disulfide on a copper foil by a chemical vapor deposition method, and after the growth is completed, coat a layer of polymethyl methacrylate (PMMA) on the surface of the molybdenum disulfide as a protection and support layer; before transfer, first take a substrate slice evaporated with the hole transport layer to transfer the prepared molybdenum disulfide; first, etch the copper foil away with a FeCl₃ solution, transfer the molybdenum disulfide to ultrapure water, then, laminate the molybdenum disulfide on the surface of the hole transport layer by a van der Waals force of a water molecule, and allow to stand for half an hour to dry naturally.

(7) Post-treatment: place the device with the transferred molybdenum disulfide on a heating plate, and bake at a temperature of 75° C. for 20 min to remove moisture inside the molybdenum disulfide, so that the molybdenum disulfide is more tightly laminated with the hole transport layer; then immerse in acetone at 20° C. for 100 min to remove the PMMA on the surface of the molybdenum disulfide.

(8) Preparation of the top electrode: first, tape around the edge of the molybdenum disulfide, and then make a circle of conductive silver adhesive on the edge of the molybdenum disulfide with an injector, the conductive silver adhesive being elongated or round on the surface of the molybdenum disulfide, and having a thickness of 0.6 μm; and finally, bake the conductive silver adhesive at 65° C. for about 10 min to fully cure the conductive silver adhesive.

FIG. 2 shows comparison of current density-voltage (J-V) curves of an InGaAs-molybdenum disulfide heterojunction solar cell with and without a hole transport layer. The reference cell has a short-circuit current density of 24.56 mA per square centimeter, an open-circuit voltage of 0.75 v, and a conversion efficiency of 13.66%. By adding a hole transport layer between InGaAs and molybdenum disulfide, the short-circuit current density of the solar cell is increased to 28.82 mA per square centimeter, the open-circuit voltage is increased to 0.80 v, and the conversion efficiency is increased to 17.06%, indicating a significant improvement in the performance of the solar cell.

The present invention aims to prepare an InGaAs-molybdenum disulfide heterojunction solar cell having a hole transport layer made of 2,2′,7,7′-tetra[N,N-bis(4-methoxyphenyl)amino]-9,9′-spirobifluorene (Spiro-OMeTAD). On the one hand, the hole transport layer can play the role of conducting a hole while blocking an electron, and can reduce the recombination of the electron and the hole, reduce the loss of a photo-generated current, and improve the efficiency of the solar cell. On the other hand, the introduction of the hole transport layer can increase the hetero-barrier, thereby increasing the open-circuit voltage and increasing the fill factor of the solar cell. Therefore, the photoelectric conversion efficiency and the fill factor of the InGaAs-molybdenum disulfide heterojunction solar cell with a hole transport layer prepared by the present invention are significantly improved.

### Embodiment 2

A preparation method of an InGaAs-molybdenum disulfide heterojunction solar cell with a hole transport layer in the present embodiment includes the following steps:

(1) Preparation of a bottom electrode: fix a 2-inch GaAs substrate on a disk, and evaporate a layer of Au electrode on the back of a GaAs substrate by an electron beam evaporation system, where the evaporation temperature is 50° C., the evaporation time is 30 min, and the Au electrode has a thickness of 150 nm.

(2) Growing of an InGaAs epitaxial layer: place the GaAs substrate evaporated with the Au electrode into a molecular beam epitaxy system to grow the InGaAs epitaxial layer, where the InGaAs epitaxial layer has a thickness of 500 nm, and a doping concentration of 1×10¹⁷ cm⁻³.

(3) Dicing: dice the GaAs substrate on which the InGaAs epitaxial layer is grown into slices having a size of 1 cm² by laser scribing.

(4) Cleaning: after dicing, sequentially ultrasonically clean the substrate for 15 min by acetone, isopropyl alcohol and ultrapure water, respectively, and then dry the surface by a dryer for use.

(5) Preparation of 2,2′,7,7′-tetra[N,N-bis(4-methoxyphenyl)amino]-9,9′-spirobifluorene (Spiro-OMeTAD) as the hole transport layer by spin coating: fix the substrate on a spin coater, and prepare the 2,2′,7,7′-tetra[N,N-bis(4-methoxyphenyl)amino]-9,9′-spirobifluorene (Spiro-OMeTAD) by spin coating, where the spin coating rate during spin coating is 4,500 rpm, the spin coating time is 35 s, and the prepared hole transport layer has a thickness of 200 nm.

(6) Transfer of molybdenum disulfide: grow the molybdenum disulfide on a copper foil by a chemical vapor deposition method, and after the growth is completed, coat a layer of polymethyl methacrylate (PMMA) on the surface of the molybdenum disulfide as a protection and support layer; before transfer, first take a device evaporated with the hole transport layer to transfer the prepared molybdenum disulfide; first, etch the copper foil away with a FeCl₃ solution, transfer the molybdenum disulfide to ultrapure water, then, laminate the molybdenum disulfide on the surface of the hole transport layer by a van der Waals force of a water molecule, and allow to stand for 40 min to dry naturally.

(7) Post-treatment: place the device with the transferred molybdenum disulfide on a heating plate, and bake at a temperature of 70° C. for 20 min to remove moisture inside the molybdenum disulfide, so that the molybdenum disulfide is more tightly laminated with the hole transport layer; then immerse in acetone at 35° C. for 30 min to remove the PMMA on the surface of the molybdenum disulfide.

(8) Preparation of a top electrode: first, tape around the edge of the molybdenum disulfide, and then make a circle of conductive silver adhesive on the edge of the molybdenum disulfide with an injector, the conductive silver adhesive being elongated, punctate or round on the surface of the molybdenum disulfide, and having a thickness of 0.6 μm; and finally, bake the conductive silver adhesive at 65° C. for about 10 min to fully cure the conductive silver adhesive.

### Embodiment 3

A preparation method of an InGaAs-molybdenum disulfide heterojunction solar cell with a hole transport layer in the present embodiment includes the following steps:

(1) Preparation of a bottom electrode: fix a 2-inch GaAs substrate on a disk, and evaporate a layer of Au electrode on the back of a GaAs substrate by an electron beam evaporation system, where the evaporation temperature is 60° C., the evaporation time is 40 min, and the Au electrode has a thickness of 200 nm.

(2) Growing of an InGaAs epitaxial layer: place the GaAs substrate evaporated with the Au electrode into a molecular beam epitaxy system to grow the InGaAs epitaxial layer, where the InGaAs epitaxial layer has a thickness of 500 nm, and a doping concentration of 1×10¹⁷ cm⁻³.

(3) Dicing: dice the GaAs substrate on which the InGaAs epitaxial layer is grown into slices having a size of 1 cm² by laser scribing.

(4) Cleaning: after dicing, sequentially ultrasonically clean the substrate for 15 min by acetone, isopropyl alcohol and ultrapure water, respectively, and then dry the surface by a dryer for use.

(5) Preparation of 2,2′,7,7′-tetra[N,N-bis(4-methoxyphenyl)amino]-9,9′-spirobifluorene (Spiro-OMeTAD) as the hole transport layer by spin coating: fix the substrate on a spin coater, and prepare the 2,2′,7,7′-tetra[N,N-bis(4-methoxyphenyl)amino]-9,9′-spirobifluorene (Spiro-OMeTAD) by spin coating, where the spin coating rate during spin coating is 3,500 rpm, the spin coating time is 35 s, and the prepared hole transport layer has a thickness of 300 nm.

(6) Transfer of molybdenum disulfide: grow the molybdenum disulfide on a copper foil by a chemical vapor deposition method, and after the growth is completed, coat a layer of polymethyl methacrylate (PMMA) on the surface of the molybdenum disulfide as a protection and support layer; before transfer, first take a device evaporated with the hole transport layer to transfer the prepared molybdenum disulfide; first, etch the copper foil away with a FeCl₃ solution, transfer the molybdenum disulfide to ultrapure water, then, laminate the molybdenum disulfide on the surface of the hole transport layer by a van der Waals force of a water molecule, and allow to stand for 30 min to dry naturally.

(7) Post-treatment: place the device with the transferred molybdenum disulfide on a heating plate, and bake at a temperature of 70° C. for 20 min to remove moisture inside the molybdenum disulfide, so that the molybdenum disulfide is more tightly laminated with the hole transport layer; then immerse in acetone at 35° C. for 30 min to remove the PMMA on the surface of the molybdenum disulfide.

(8) Preparation of a top electrode: first, tape around the edge of the molybdenum disulfide, and then make a circle of conductive silver adhesive on the edge of the molybdenum disulfide with an injector, the conductive silver adhesive being elongated, punctate or round on the surface of the molybdenum disulfide, and having a thickness of 1.5 μm; and finally, bake the conductive silver adhesive at 70° C. for about 20 min to fully cure the conductive silver adhesive.

The above embodiments are preferred implementations of the present invention, but the implementations of the present invention are not limited to these embodiments, and any other changes, modifications, substitutions, combinations and simplifications made without departing from the spirit and principle of the present invention shall be equivalent replacement means, and shall be included in the protection scope of the present invention.

1. A heterojunction solar cell with a hole transport layer, wherein the solar cell comprises a bottom electrode, a GaAs substrate, an InGaAs epitaxial layer, a hole transport layer, a molybdenum disulfide layer and a top electrode in order from bottom to top; the hole transport layer is a 2,2′,7,7′-tetra[N,N-bis(4-methoxyphenyl)amino]-9,9′-spirobifluorene film.

2. The heterojunction solar cell with a hole transport layer according to claim 1, wherein the hole transport layer has a thickness of 50-500 nm.

3. The heterojunction solar cell with a hole transport layer according to claim 1, wherein the GaAs substrate is N-type, having a size of 1-4 inches, and a doping concentration of 1×10¹⁷-3×10¹⁸ cm⁻³.

4. The heterojunction solar cell with a hole transport layer according to claim 1, wherein the InGaAs epitaxial layer is N-type InGaAs, having a size of 1-4 inches, a doping concentration of 1×10¹⁷-4×10¹⁸ cm⁻³, and a thickness of 100-1,000 nm.

5. The heterojunction solar cell with a hole transport layer according to claim 1, wherein the number of layers of the molybdenum disulfide is 1-8.

6. The heterojunction solar cell with a hole transport layer according to claim 1, wherein the bottom electrode has a thickness of 40-600 nm.

7. The heterojunction solar cell with a hole transport layer according to claim 1, wherein the top electrode is a silver conductive silver adhesive or silver wire, and has a thickness of 0.2-1 μm.

8. A preparation method of the heterojunction solar cell with a hole transport layer according to claim 1, comprising the following steps:
(1) preparation of the bottom electrode: fixing the GaAs substrate on a disk, and evaporating a layer of bottom electrode on the back of the GaAs substrate by an electron beam evaporation method, wherein the evaporation temperature is 10-100° C., and the evaporation time is 10-60 min;
(2) growing of the InGaAs epitaxial layer: placing the GaAs substrate evaporated with the bottom electrode into a molecular beam epitaxy system to grow the InGaAs epitaxial layer;
(3) dicing: dicing the GaAs substrate on which the InGaAs epitaxial layer is grown into slices by laser scribing;
(4) cleaning the substrate;
(5) preparation of 2,2′,7,7′-tetra[N,N-bis(4-methoxyphenyl)amino]-9,9′-spirobifluorene as the hole transport layer by spin coating: fixing the substrate on a spin coater, and preparing the 2,2′,7,7′-tetra[N,N-bis(4-methoxyphenyl)amino]-9,9′-spirobifluorene by spin coating, wherein the spin coating rate during spin coating is 1,000-5,000 rpm, and the spin coating time is 10-60 s;
(6) transfer of the molybdenum disulfide: growing the molybdenum disulfide on a copper foil by a chemical vapor deposition method, and after the growth is completed, coating a layer of polymethyl methacrylate (PMMA) on the surface of the molybdenum disulfide as a protection and support layer; before transfer, first taking a substrate slice evaporated with the hole transport layer to transfer the prepared molybdenum disulfide; first, etching the copper foil away with a FeCl₃ solution, transferring the molybdenum disulfide to ultrapure water, then, laminating the molybdenum disulfide on the surface of the hole transport layer by a van der Waals force of a water molecule, and allowing to stand to dry naturally;
(7) post-treatment: placing the device with the transferred molybdenum disulfide on a heating plate, and baking at a temperature of 60-200° C. for 5-30 min to remove moisture inside the molybdenum disulfide, so that the molybdenum disulfide is more tightly laminated with the hole transport layer; then immersing in acetone at 20-80° C. for 5-15 min to remove the PMMA on the surface of the molybdenum disulfide; and
(8) preparation of the top electrode: first, taping around the edge of the molybdenum disulfide, and then making a circle of conductive silver adhesive on the edge of the molybdenum disulfide with an injector, the conductive silver adhesive having a thickness of 0.2-2 μm; and finally, baking the conductive silver adhesive at 30-100° C. for 2-20 min to fully cure the conductive silver adhesive.

9. The preparation method of the heterojunction solar cell with a hole transport layer according to claim 8, wherein the conductive silver adhesive is elongated or round on the surface of the molybdenum disulfide.

10. The preparation method of the heterojunction solar cell with a hole transport layer according to claim 8, wherein the cleaning the substrate according to the step (4) is specifically: after dicing, sequentially ultrasonically cleaning the substrate for 5-20 min by acetone, isopropyl alcohol and ultrapure water, respectively, and then drying the surface by a dryer for use.

11. A preparation method of the heterojunction solar cell with a hole transport layer according to claim 2, comprising the following steps:
(1) preparation of the bottom electrode: fixing the GaAs substrate on a disk, and evaporating a layer of bottom electrode on the back of the GaAs substrate by an electron beam evaporation method, wherein the evaporation temperature is 10-100° C., and the evaporation time is 10-60 min;
(2) growing of the InGaAs epitaxial layer: placing the GaAs substrate evaporated with the bottom electrode into a molecular beam epitaxy system to grow the InGaAs epitaxial layer;
(3) dicing: dicing the GaAs substrate on which the InGaAs epitaxial layer is grown into slices by laser scribing;
(4) cleaning the substrate;
(5) preparation of 2,2′,7,7′-tetra[N,N-bis(4-methoxyphenyl)amino]-9,9′-spirobifluorene as the hole transport layer by spin coating: fixing the substrate on a spin coater, and preparing the 2,2′,7,7′-tetra[N,N-bis(4-methoxyphenyl)amino]-9,9′-spirobifluorene by spin coating, wherein the spin coating rate during spin coating is 1,000-5,000 rpm, and the spin coating time is 10-60 s;
(6) transfer of the molybdenum disulfide: growing the molybdenum disulfide on a copper foil by a chemical vapor deposition method, and after the growth is completed, coating a layer of polymethyl methacrylate (PMMA) on the surface of the molybdenum disulfide as a protection and support layer; before transfer, first taking a substrate slice evaporated with the hole transport layer to transfer the prepared molybdenum disulfide; first, etching the copper foil away with a FeCl₃ solution, transferring the molybdenum disulfide to ultrapure water, then, laminating the molybdenum disulfide on the surface of the hole transport layer by a van der Waals force of a water molecule, and allowing to stand to dry naturally;
(7) post-treatment: placing the device with the transferred molybdenum disulfide on a heating plate, and baking at a temperature of 60-200° C. for 5-30 min to remove moisture inside the molybdenum disulfide, so that the molybdenum disulfide is more tightly laminated with the hole transport layer; then immersing in acetone at 20-80° C. for 5-15 min to remove the PMMA on the surface of the molybdenum disulfide; and
(8) preparation of the top electrode: first, taping around the edge of the molybdenum disulfide, and then making a circle of conductive silver adhesive on the edge of the molybdenum disulfide with an injector, the conductive silver adhesive having a thickness of 0.2-2 μm; and finally, baking the conductive silver adhesive at 30-100° C. for 2-20 min to fully cure the conductive silver adhesive.

12. A preparation method of the heterojunction solar cell with a hole transport layer according to claim 3, comprising the following steps:
(1) preparation of the bottom electrode: fixing the GaAs substrate on a disk, and evaporating a layer of bottom electrode on the back of the GaAs substrate by an electron beam evaporation method, wherein the evaporation temperature is 10-100° C., and the evaporation time is 10-60 min;
(2) growing of the InGaAs epitaxial layer: placing the GaAs substrate evaporated with the bottom electrode into a molecular beam epitaxy system to grow the InGaAs epitaxial layer;
(3) dicing: dicing the GaAs substrate on which the InGaAs epitaxial layer is grown into slices by laser scribing;
(4) cleaning the substrate;
(5) preparation of 2,2′,7,7′-tetra[N,N-bis(4-methoxyphenyl)amino]-9,9′-spirobifluorene as the hole transport layer by spin coating: fixing the substrate on a spin coater, and preparing the 2,2′,7,7′-tetra[N,N-bis(4-methoxyphenyl)amino]-9,9′-spirobifluorene by spin coating, wherein the spin coating rate during spin coating is 1,000-5,000 rpm, and the spin coating time is 10-60 s;
(6) transfer of the molybdenum disulfide: growing the molybdenum disulfide on a copper foil by a chemical vapor deposition method, and after the growth is completed, coating a layer of polymethyl methacrylate (PMMA) on the surface of the molybdenum disulfide as a protection and support layer; before transfer, first taking a substrate slice evaporated with the hole transport layer to transfer the prepared molybdenum disulfide; first, etching the copper foil away with a FeCl₃ solution, transferring the molybdenum disulfide to ultrapure water, then, laminating the molybdenum disulfide on the surface of the hole transport layer by a van der Waals force of a water molecule, and allowing to stand to dry naturally;
(7) post-treatment: placing the device with the transferred molybdenum disulfide on a heating plate, and baking at a temperature of 60-200° C. for 5-30 min to remove moisture inside the molybdenum disulfide, so that the molybdenum disulfide is more tightly laminated with the hole transport layer; then immersing in acetone at 20-80° C. for 5-15 min to remove the PMMA on the surface of the molybdenum disulfide; and
(8) preparation of the top electrode: first, taping around the edge of the molybdenum disulfide, and then making a circle of conductive silver adhesive on the edge of the molybdenum disulfide with an injector, the conductive silver adhesive having a thickness of 0.2-2 μm; and finally, baking the conductive silver adhesive at 30-100° C. for 2-20 min to fully cure the conductive silver adhesive.

13. A preparation method of the heterojunction solar cell with a hole transport layer according to claim 4, comprising the following steps:
(1) preparation of the bottom electrode: fixing the GaAs substrate on a disk, and evaporating a layer of bottom electrode on the back of the GaAs substrate by an electron beam evaporation method, wherein the evaporation temperature is 10-100° C., and the evaporation time is 10-60 min;
(2) growing of the InGaAs epitaxial layer: placing the GaAs substrate evaporated with the bottom electrode into a molecular beam epitaxy system to grow the InGaAs epitaxial layer;
(3) dicing: dicing the GaAs substrate on which the InGaAs epitaxial layer is grown into slices by laser scribing;
(4) cleaning the substrate;
(5) preparation of 2,2′,7,7′-tetra[N,N-bis(4-methoxyphenyl)amino]-9,9′-spirobifluorene as the hole transport layer by spin coating: fixing the substrate on a spin coater, and preparing the 2,2′,7,7′-tetra[N,N-bis(4-methoxyphenyl)amino]-9,9′-spirobifluorene by spin coating, wherein the spin coating rate during spin coating is 1,000-5,000 rpm, and the spin coating time is 10-60 s;
(6) transfer of the molybdenum disulfide: growing the molybdenum disulfide on a copper foil by a chemical vapor deposition method, and after the growth is completed, coating a layer of polymethyl methacrylate (PMMA) on the surface of the molybdenum disulfide as a protection and support layer; before transfer, first taking a substrate slice evaporated with the hole transport layer to transfer the prepared molybdenum disulfide; first, etching the copper foil away with a FeCl₃ solution, transferring the molybdenum disulfide to ultrapure water, then, laminating the molybdenum disulfide on the surface of the hole transport layer by a van der Waals force of a water molecule, and allowing to stand to dry naturally;
(7) post-treatment: placing the device with the transferred molybdenum disulfide on a heating plate, and baking at a temperature of 60-200° C. for 5-30 min to remove moisture inside the molybdenum disulfide, so that the molybdenum disulfide is more tightly laminated with the hole transport layer; then immersing in acetone at 20-80° C. for 5-15 min to remove the PMMA on the surface of the molybdenum disulfide; and
(8) preparation of the top electrode: first, taping around the edge of the molybdenum disulfide, and then making a circle of conductive silver adhesive on the edge of the molybdenum disulfide with an injector, the conductive silver adhesive having a thickness of 0.2-2 ∥m; and finally, baking the conductive silver adhesive at 30-100° C. for 2-20 min to fully cure the conductive silver adhesive.

14. A preparation method of the heterojunction solar cell with a hole transport layer according to claim 5, comprising the following steps:
(1) preparation of the bottom electrode: fixing the GaAs substrate on a disk, and evaporating a layer of bottom electrode on the back of the GaAs substrate by an electron beam evaporation method, wherein the evaporation temperature is 10-100° C., and the evaporation time is 10-60 min;
(2) growing of the InGaAs epitaxial layer: placing the GaAs substrate evaporated with the bottom electrode into a molecular beam epitaxy system to grow the InGaAs epitaxial layer;
(3) dicing: dicing the GaAs substrate on which the InGaAs epitaxial layer is grown into slices by laser scribing;
(4) cleaning the substrate;
(5) preparation of 2,2′,7,7′-tetra[N,N-bis(4-methoxyphenyl)amino]-9,9′-spirobifluorene as the hole transport layer by spin coating: fixing the substrate on a spin coater, and preparing the 2,2′,7,7′-tetra[N,N-bis(4-methoxyphenyl)amino]-9,9′-spirobifluorene by spin coating, wherein the spin coating rate during spin coating is 1,000-5,000 rpm, and the spin coating time is 10-60 s;
(6) transfer of the molybdenum disulfide: growing the molybdenum disulfide on a copper foil by a chemical vapor deposition method, and after the growth is completed, coating a layer of polymethyl methacrylate (PMMA) on the surface of the molybdenum disulfide as a protection and support layer; before transfer, first taking a substrate slice evaporated with the hole transport layer to transfer the prepared molybdenum disulfide; first, etching the copper foil away with a FeCl₃ solution, transferring the molybdenum disulfide to ultrapure water, then, laminating the molybdenum disulfide on the surface of the hole transport layer by a van der Waals force of a water molecule, and allowing to stand to dry naturally;
(7) post-treatment: placing the device with the transferred molybdenum disulfide on a heating plate, and baking at a temperature of 60-200° C. for 5-30 min to remove moisture inside the molybdenum disulfide, so that the molybdenum disulfide is more tightly laminated with the hole transport layer; then immersing in acetone at 20-80° C. for 5-15 min to remove the PMMA on the surface of the molybdenum disulfide; and
(8) preparation of the top electrode: first, taping around the edge of the molybdenum disulfide, and then making a circle of conductive silver adhesive on the edge of the molybdenum disulfide with an injector, the conductive silver adhesive having a thickness of 0.2-2 μm; and finally, baking the conductive silver adhesive at 30-100° C. for 2-20 min to fully cure the conductive silver adhesive.

15. A preparation method of the heterojunction solar cell with a hole transport layer according to claim 6, comprising the following steps:
(1) preparation of the bottom electrode: fixing the GaAs substrate on a disk, and evaporating a layer of bottom electrode on the back of the GaAs substrate by an electron beam evaporation method, wherein the evaporation temperature is 10-100° C., and the evaporation time is 10-60 min;
(2) growing of the InGaAs epitaxial layer: placing the GaAs substrate evaporated with the bottom electrode into a molecular beam epitaxy system to grow the InGaAs epitaxial layer;
(3) dicing: dicing the GaAs substrate on which the InGaAs epitaxial layer is grown into slices by laser scribing;
(4) cleaning the substrate;
(5) preparation of 2,2′,7,7′-tetra[N,N-bis(4-methoxyphenyl)amino]-9,9′-spirobifluorene as the hole transport layer by spin coating: fixing the substrate on a spin coater, and preparing the 2,2′,7,7′-tetra[N,N-bis(4-methoxyphenyl)amino]-9,9′-spirobifluorene by spin coating, wherein the spin coating rate during spin coating is 1,000-5,000 rpm, and the spin coating time is 10-60 s;
(6) transfer of the molybdenum disulfide: growing the molybdenum disulfide on a copper foil by a chemical vapor deposition method, and after the growth is completed, coating a layer of polymethyl methacrylate (PMMA) on the surface of the molybdenum disulfide as a protection and support layer; before transfer, first taking a substrate slice evaporated with the hole transport layer to transfer the prepared molybdenum disulfide; first, etching the copper foil away with a FeCl₃ solution, transferring the molybdenum disulfide to ultrapure water, then, laminating the molybdenum disulfide on the surface of the hole transport layer by a van der Waals force of a water molecule, and allowing to stand to dry naturally;
(7) post-treatment: placing the device with the transferred molybdenum disulfide on a heating plate, and baking at a temperature of 60-200° C. for 5-30 min to remove moisture inside the molybdenum disulfide, so that the molybdenum disulfide is more tightly laminated with the hole transport layer; then immersing in acetone at 20-80° C. for 5-15 min to remove the PMMA on the surface of the molybdenum disulfide; and
(8) preparation of the top electrode: first, taping around the edge of the molybdenum disulfide, and then making a circle of conductive silver adhesive on the edge of the molybdenum disulfide with an injector, the conductive silver adhesive having a thickness of 0.2-2 μm; and finally, baking the conductive silver adhesive at 30-100° C. for 2-20 min to fully cure the conductive silver adhesive.

16. A preparation method of the heterojunction solar cell with a hole transport layer according to claim 7, comprising the following steps:
(1) preparation of the bottom electrode: fixing the GaAs substrate on a disk, and evaporating a layer of bottom electrode on the back of the GaAs substrate by an electron beam evaporation method, wherein the evaporation temperature is 10-100° C., and the evaporation time is 10-60 min;
(2) growing of the InGaAs epitaxial layer: placing the GaAs substrate evaporated with the bottom electrode into a molecular beam epitaxy system to grow the InGaAs epitaxial layer;
(3) dicing: dicing the GaAs substrate on which the InGaAs epitaxial layer is grown into slices by laser scribing;
(4) cleaning the substrate;
(5) preparation of 2,2′,7,7′-tetra[N,N-bis(4-methoxyphenyl)amino]-9,9′-spirobifluorene as the hole transport layer by spin coating: fixing the substrate on a spin coater, and preparing the 2,2′,7,7′-tetra[N,N-bis(4-methoxyphenyl)amino]-9,9′-spirobifluorene by spin coating, wherein the spin coating rate during spin coating is 1,000-5,000 rpm, and the spin coating time is 10-60 s;
(6) transfer of the molybdenum disulfide: growing the molybdenum disulfide on a copper foil by a chemical vapor deposition method, and after the growth is completed, coating a layer of polymethyl methacrylate (PMMA) on the surface of the molybdenum disulfide as a protection and support layer; before transfer, first taking a substrate slice evaporated with the hole transport layer to transfer the prepared molybdenum disulfide; first, etching the copper foil away with a FeCl₃ solution, transferring the molybdenum disulfide to ultrapure water, then, laminating the molybdenum disulfide on the surface of the hole transport layer by a van der Waals force of a water molecule, and allowing to stand to dry naturally;
(7) post-treatment: placing the device with the transferred molybdenum disulfide on a heating plate, and baking at a temperature of 60-200° C. for 5-30 min to remove moisture inside the molybdenum disulfide, so that the molybdenum disulfide is more tightly laminated with the hole transport layer; then immersing in acetone at 20-80° C. for 5-15 min to remove the PMMA on the surface of the molybdenum disulfide; and
(8) preparation of the top electrode: first, taping around the edge of the molybdenum disulfide, and then making a circle of conductive silver adhesive on the edge of the molybdenum disulfide with an injector, the conductive silver adhesive having a thickness of 0.2-2 μm; and finally, baking the conductive silver adhesive at 30-100° C. for 2-20 min to fully cure the conductive silver adhesive.

17. The preparation method of the heterojunction solar cell with a hole transport layer according to claim 9, wherein the conductive silver adhesive is elongated or round on the surface of the molybdenum disulfide.

18. The preparation method of the heterojunction solar cell with a hole transport layer according to claim 10, wherein the conductive silver adhesive is elongated or round on the surface of the molybdenum disulfide.

19. The preparation method of the heterojunction solar cell with a hole transport layer according to claim 11, wherein the conductive silver adhesive is elongated or round on the surface of the molybdenum disulfide.

20. The preparation method of the heterojunction solar cell with a hole transport layer according to claim 12, wherein the conductive silver adhesive is elongated or round on the surface of the molybdenum disulfide.
